(19) United States
(12) Patent Application Publication
(10) Pub. No.: US 2009/0124079 A1
(43) Pub. Date: May 14, 2009

(54) METHOD FOR FABRICATING A CONDUCTIVE PLUG

(76) Inventors: Jen-Jui Huang, Taoyuan County (TW); Chih-Ching Lin, Taoyuan County (TW); Kuo-Chung Chen, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/042,347

(22) Filed: Mar. 5, 2008

(30) Foreign Application Priority Data
Nov. 8, 2007 (TW) 096142211

(51) Int. Cl. H01L 21/768

(52) U.S. Cl. 438/675; 257/E21.586

(57) ABSTRACT

A method for fabricating a conductive plug includes the steps of providing a substrate having at least a gate structure thereon, a first dielectric layer covering a surface of the substrate, a second dielectric layer disposed on the first dielectric layer, and at least a metal line formed within the second dielectric layer; forming a hard mask plug on the second dielectric layer; forming a third dielectric layer covering the second dielectric layer and the hard mask plug; removing a portion of the third dielectric layer to expose the hard mask plug; removing the hard mask plug to form a plug hole; and forming the conductive plug within the plug hole to electrically connect with the gate structure.

### BACKGROUND OF THE INVENTION

1. Field of the Invention

The present invention relates to a method of fabricating a conductive plug, and more particularly, to a method of fabricating a tungsten plug (W-plug) that avoids shorting.

2. Description of the Prior Art

A dynamic random access memory (DRAM) is an element within an integrated circuit that is formed by a large number of memory cells. Each memory cell is composed of a metal oxide semiconductor (MOS) transistor and a capacitor, and each bit of data is stored in the capacitor. Each MOS transistor is electrically connected with a capacitor by several word lines and bit lines, so as to determine the address of every memory cell.

A DRAM is in the class of volatile memory devices, since it loses its data when the power supply is removed. An advantage of a DRAM over a static random access memory (SRAM), which is also in the class of volatile memory devices, is its structural simplicity: only one transistor and a capacitor are required per bit, compared to six or four transistors in an SRAM. This allows a DRAM to reach very high integration density.

Please refer to FIG.1 to FIG. 3, which are cross-sections illustrating a conventional method of fabricating a bit line (i.e. tungsten plug; W-plug) in a DRAM. FIG. 1 to FIG. 3 only shows a gate structure and a metal line.

As shown in FIG. 1, a semiconductor substrate 100 is first provided such as a silicon substrate or a silicon-on-insulator (SOI) substrate, etc. A gate structure 102, which includes a gate conductor 104 and a spacer 106, is formed on the semiconductor substrate 100. A first dielectric layer 108 is then deposited on the semiconductor substrate 100, and the first dielectric layer 108 covers the surface of the gate structure 102.

A second dielectric layer 110 is deposited on the first dielectric layer 108, and at least a metal line 112, which is the bit line in the DRAM, is formed within the second dielectric layer 110.

A third dielectric layer 114 is then deposited on the second dielectric layer 110 and the metal line 112. Afterward, a patterned mask 116 is formed on the third dielectric layer 114 to define a plug opening 118 by suitable lithography processes, such as exposure, and development, etc.

As shown in FIG. 2, an etching process, such as an anisotropic dry etching process, is carried out to form a plug hole 120 within the third dielectric layer 114. A strip process, such as an ashing process, is then carried out to remove the patterned mask 116.

As shown in FIG. 3, a conformal liner 122 is deposited on the third dielectric layer 114. The liner 122 covers the inner surface of the plug hole 120, but it does not fill up the plug hole 120. In general, the liner 122 is composed of titanium nitride (TiN), etc.

Subsequently, a deposition process such as a chemical vapor deposition (CVD) process is carried out to deposit a conformal tungsten layer 124, and the tungsten layer 124 fills up the plug hole 120. Afterward, a chemical mechanical polishing (CMP) is carried out to remove the tungsten layer 124 and the liner 122 on the surface of the third dielectric layer 114; therefore, a tungsten plug (W-plug) 126 is formed within the third dielectric layer 114.

In an ideal situation, the tungsten plug 126 should be aligned and formed exactly on the metal line 112. However, as the critical dimensions of the plug holes and the metal lines continuously decrease with the advanced miniaturization of the semiconductor integrated circuits, a phenomenon of lithography misalignment easily occurs while defining the plug holes or the metal lines in the lithography processes.

If the lithography misalignment occurs, the dielectric layer underneath the plug hole and even the gate conductor 104 will be etched in the process of etching the plug hole 120. Therefore, after filling the plug hole 120 with tungsten, a short circuit occurs because the metal line 112 is electrically connected with the gate conductor 104. As shown in FIG. 4, the plug opening 118 is shifted because of the lithography misalignment. Therefore while etching the plug hole 120, the etching process does not stop at the metal lines 112, and the second dielectric layer 110 where the metal line 112 is located, the first dielectric layer 114, and even the gate conductor 104 are also etched in extreme cases.

Accordingly, a method of fabricating a conductive plug is provided for improving above-mentioned deficiencies of the conventional methods.

### SUMMARY OF THE INVENTION

The present invention relates to a method of fabricating a conductive plug, and more particularly, to a method of fabricating a bit line tungsten plug (W-plug) in a DRAM to improve upon the short circuit that occurs between the gate structure and the bit line in conventional methods.

According to the claimed invention, a method for fabricating a conductive plug is provided that comprises steps of providing a substrate having at least a gate structure thereon, a first dielectric layer covering a surface of the substrate, a second dielectric layer disposed on the first dielectric layer, and at least a metal line formed within the second dielectric layer; forming a hard mask plug on the second dielectric layer; forming a third dielectric layer covering the second dielectric layer and the hard mask plug; removing a portion of the third dielectric layer to expose the hard mask plug; removing the hard mask plug to form a plug hole; and forming the conductive plug within the plug hole to electrically connect with the gate structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 3 are cross-sections illustrating a conventional method of fabricating a tungsten plug (W-plug) of a DRAM.

FIG. 4 is a cross-section illustrating a conventional method of fabricating a plug hole when the lithography misalignment occurs.

FIG. 5 to FIG. 9 are cross-sections illustrating a method of fabricating a conductive plug in a DRAM according to a preferred embodiment of the present invention.

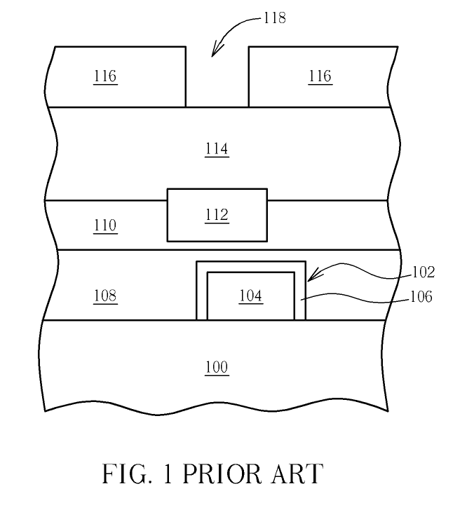

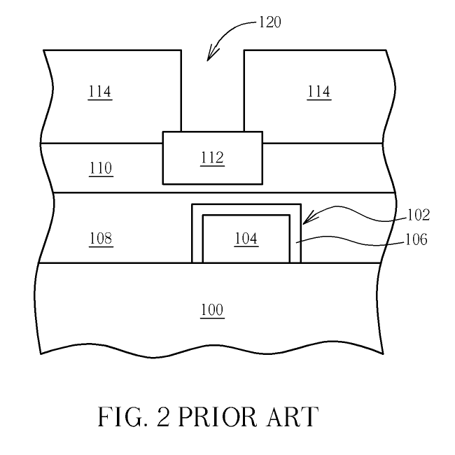

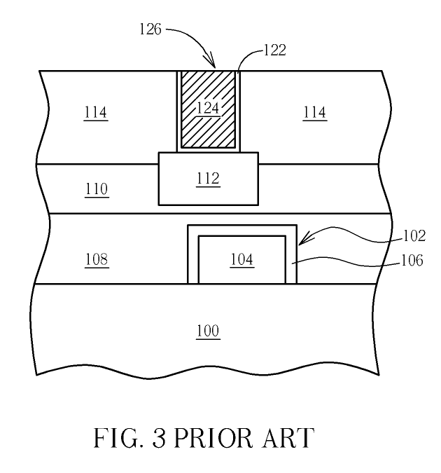

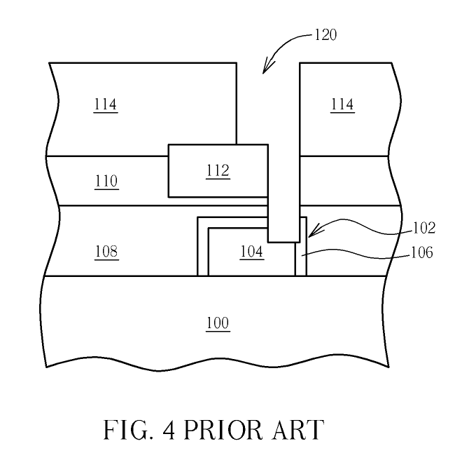

### DETAILED DESCRIPTION

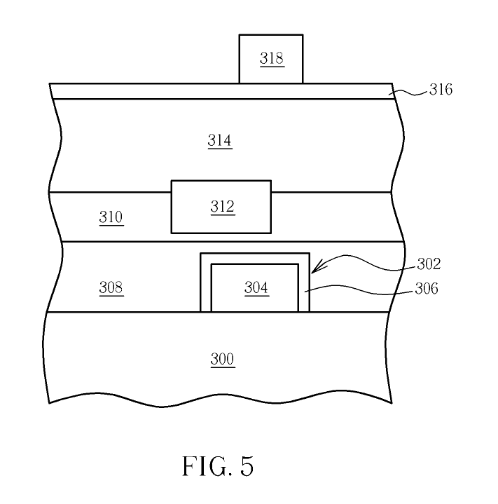

Please refer to FIG. 5 to FIG. 9, which are cross-sections illustrating a method of fabricating a conductive plug according to a preferred embodiment of the present invention. FIG. 5 to FIG. 9 only shows a gate structure and a metal line for highlighting the characteristic of the present invention and simplifying the illustration.

As shown in FIG. 5, initially a semiconductor substrate 300 is provided such as a silicon substrate or a silicon-on-insulator (SOI) substrate, etc. The semiconductor substrate 300 includes a gate structure 302 thereon, and the gate structure 302 further includes a gate conductor 304 and a spacer 306 surrounding the gate conductor 304. A first dielectric layer 308 is then deposited on the semiconductor substrate 300, and covers the surface of the gate structure 302. Next, a second dielectric layer 310 is deposited on the first dielectric layer 308. A metal line 312 is formed within the second dielectric layer 310. The metal line 312 may be the bit line in the DRAM.

According to the preferred embodiment of the present invention, the first dielectric layer 308 and the second dielectric layer 310 are composed of silicon oxide components such as borosilicate glass (BSG), and borophosphosilicate glass (BPSG), etc. The metal line 312 may be, formed by performing an etching process with the usage of a patterned mask (not shown) after depositing the second dielectric layer 310, so as to form a metal line recess (not shown), and by filling in the recess with a suitable metal material such as tungsten (W) or the like.

Subsequently, a hard mask layer 314 is deposited on the second dielectric layer 310 and the metal line 312. It is preferable to selectively deposit a cap layer 316 on the hard mask layer 314. The hard mask layer 314 has a higher etching selectivity compared to that of the first dielectric layer 308. According to the preferred embodiment of the present invention, the hard mask layer 314 is a carbon hard mask, and the cap layer 316 is composed of silicon-oxy-nitride (SiON) layer having a thickness of about 40 to 50 nm. The etching selectivity of the silicon-oxy-nitride (SiON) layer to the carbon hard mask is about 20. The silicon-oxy-nitride (SiON) layer can also be used as an etching mask and an anti-reflection coating (ARC). According to the preferred embodiment of the present invention, the hard mask layer 314 may also be a polysilicon layer, and the cap layer 316 may be a silicon nitride layer. An additional silicon-oxy-nitride (SiON) layer may be deposited on the cap layer 316 to be used as an anti-reflection coating. Afterward, a patterned mask 318, such as a photoresist layer, is coated on the cap layer 316 to define the position of the conductive plug to be formed in the following fabrication processes.

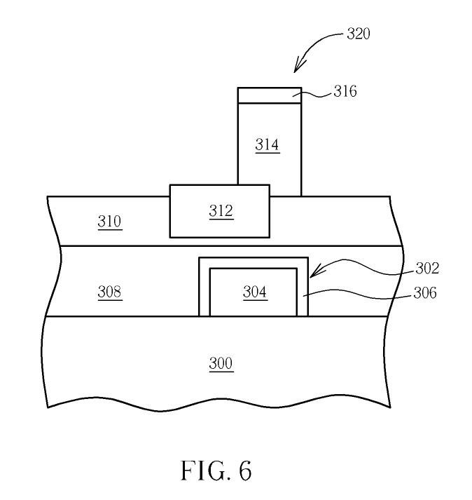

As shown in FIG. 6, an etching process is carried out to remove the cap layer 316 and the hard mask layer 314 not covered by the patterned mask 318. For example, an anisotropic dry etching process is carried out using the patterned mask 318 as the etching mask to transfer the pattern of the patterned mask 318 to the cap layer 316. The patterned mask 318 is then removed. Next, another etching process using the cap layer 316 as the etching mask is carried out to etch the hard mask layer 314 until the second dielectric layer 310 and the metal line 312 are exposed. As a result, a hard mask plug 320 composing the cap layer 316 and the hard mask layer 314 is formed on both the second dielectric layer 310 and the metal line 312. It should be noted that, because the hard mask layer 316 is a carbon hard mask or a polysilicon layer, which has a relatively high etching selectivity to the second dielectric layer 310 so that the etching process stops on the second dielectric layer 310 in the etching process of removing the hard mask layer 314 and does not etch the second dielectric layer 310 any more.

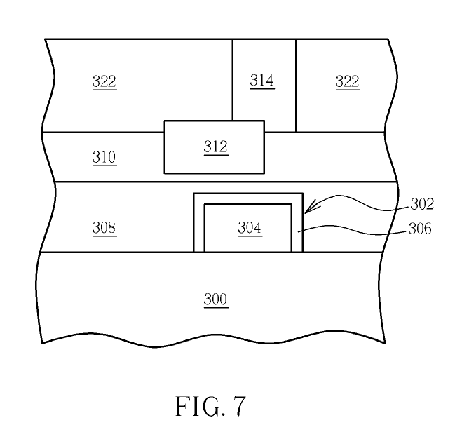

As shown in FIG. 7, a deposition process is carried out to deposit a third dielectric layer 322 covering the second dielectric layer 310 and the metal line 312. The third dielectric layer 322 also covers the hard mask plug 320. According to the preferred embodiment of the present invention, the third dielectric layer 322 is composed of silicon oxide components such as borosilicate glass (BSG), and borophosphosilicate glass (BPSG), etc; and the hard mask layer 314 also has a higher etching selectivity to the third dielectric layer 322.

Subsequently, a chemical mechanical polishing (CMP) process is carried out to remove a portion of the third dielectric layer 322 and the cap layer 316 above the hard mask layer 314 to expose the surface of the hard mask plug 320. According to the preferred embodiment of the present invention, a deglaze process may be performed after the chemical mechanical polishing (CMP) process to remove the remaining cap layer 316 left on the hard mask layer 314.

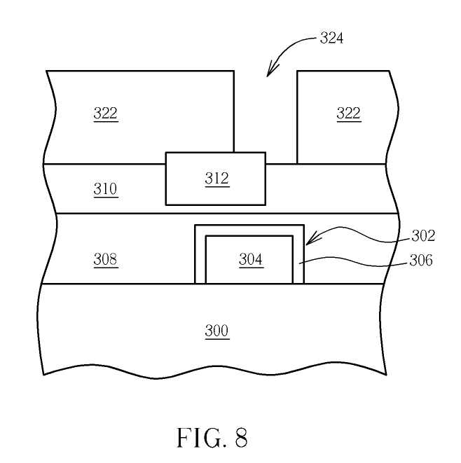

As shown in FIG. 8, the hard mask layer 314 within the third dielectric layer is removed to form a plug hole 324. According to the preferred embodiment of the present invention, as the hard mask layer 314 is a carbon hard mask, an ashing process usually used for stripping the photoresist can be adopted. For example, a dry etching process including the ozone plasma is carried out to remove the hard mask layer 314. On the other hand, as the hard mask layer 314 is a polysilicon layer, a wet etching process can be used to remove the hard mask layer 314.

It should be noted that, because the hard mask layer 314 of the present invention has relatively higher etching selectivity to both the second dielectric layer 310 and the third dielectric layer 322 so that during the ashing process or the wet etching process of removing the hard mask layer 314, the adjacent dielectric layer 310 and the dielectric layer 322 are not damaged.

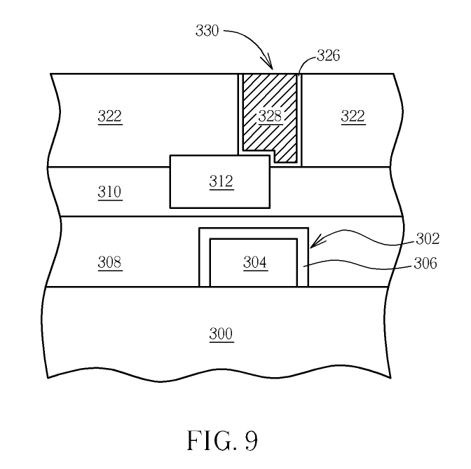

As shown in FIG. 9, a liner 326 is conformably deposited on the third dielectric layer 322. The liner 326 covers the interior surface of the plug hole 324, but does not fill the plug hole 324. According to the preferred embodiment of the present invention, the liner 326 is composed of titanium nitride (TiN).

Subsequently, a deposition process, such as a chemical vapor deposition (CVD) process is carried out to deposit a metal layer 328 on the liner 326. The metal layer 328 fills the plug hole 324. Finally, a chemical mechanical polishing (CMP) process is carried out to remove the metal layer 328 and the liner 326 above the third dielectric layer 322 so that a conductive plug 330 is formed within the third dielectric layer 322.

According to the preferred embodiment of the present invention, the metal layer 328 is composed of metal materials, such as tungsten, etc. The conductive plug 330 can be electrically connected with the metal line 312 and the upper metal line, the power line, or the bonding pad fabricated in the following processes.

The feature of the present invention is to replace the conventional dielectric layer where the plugs are formed by a hard mask layer; and etch the hard mask layer to form a hard mask plug. The position of the hard mask plug is where the conductive plug will be formed in following processes. Because the hard mask layer is composed of materials with higher etching selectivities to the dielectric layer underneath the hard mask layer, even if the lithography misalignment happens to the metal lines, the etching process of etching the plug hole will not etch the dielectric layer underneath the hard mask layer or the gate conductor. As a result, the short circuit, which is caused by the electrical connection between the conductive plug and the gate structure after filling the plug hole with the metal, will not occur.

In addition, since the hard mask layer possesses the features of having a higher etching selectivity to the dielectric layer underneath the hard mask layer and being easily removable, the problem of damaging the adjacent dielectric layers during the process of removing the hard mask plug will not occur.

It should be noted that the method of the present invention is not limited to fabricate the conductive plug above the first interconnection metal line, and may also be used for fabricating the conductive plugs to connect between the other interconnection metal lines or the conductive layers within different layers.

Those skilled in the art will readily observe that numerous modifications and alterations of the device and method may be made while retaining the teachings of the invention.

What is claimed is:

1. A method of fabricating a conductive plug in a substrate having at least a gate structure thereon, a first dielectric layer formed on top of the substrate, and an intermediate dielectric layer disposed on the first dielectric layer, comprising the steps of:
forming a hard mask plug above the first dielectric layer;
removing the hard mask plug to define a position of a conductive plug; and
forming the conductive plug in the position such that the conductive plug is free of electrical connection to the gate structure.

2. The method as claimed in claim 1, wherein the intermediate dielectric layer further comprises a metal line in the second dielectric layer to electrically connect to the conductive plug.

3. The method according to claim 1, wherein the intermediate dielectric layer further comprises a second dielectric layer on top of the intermediate dielectric layer.

4. The method according to claim 3, wherein the first dielectric layer, the intermediate dielectric layer, and the second dielectric layer all comprise silicon oxide.

5. The method according to claim 1, wherein the hard mask plug forming step comprises:
forming a hard mask layer on the second dielectric layer;
forming a cap layer on the hard mask layer;
forming a patterned mask on the cap layer to define a position of the conductive plug; and
removing the cap layer and the hard mask layer not covered by the patterned mask.

6. The method according to claim 5, wherein the hard mask layer has a higher etching selectivity to the first dielectric layer, the second dielectric layer, and the third dielectric layer.

7. The method according to claim 5, wherein the hard mask layer comprises a carbon hard mask.

8. The method according to claim 7, wherein the cap layer comprises a silicon-oxy-nitride (SiON) layer.

9. The method according to claim 7, wherein an ashing process is carried out to remove the hard mask plug.

10. The method according to claim 5, wherein the hard mask layer comprises a polysilicon layer.

11. The method according to claim 10, wherein the cap layer comprises a silicon nitride (SiN) layer.
